(19) United States
(12) Patent Application Publication
(10) Pub. No.: US 2005/0270826 A1
(43) Pub. Date: Dec. 8, 2005

(54) Semiconductor memory device and method for producing a semiconductor memory device

(76) Inventors: Thomas Mikolajick, Dresden (DE); Wolfgang Werner, Muenchen (DE); Helmut Klose, Augsburg (DE); Hyang-Sook Klose, Augsburg (DE); Jan Aram Klose, Augsburg (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/137,778

(22) Filed: May 26, 2005

Related U.S. Application Data
(63) Continuation of application No. PCT/DE03/03885, filed on Nov. 24, 2003.

(30) Foreign Application Priority Data
Nov. 26, 2002 (DE) 102 55 117.0

(51) Int. Cl. G11C 11/00

(52) U.S. Cl. 365/154

(57) ABSTRACT

A semiconductor memory device with a phase transformation memory effect includes at least one memory element in a semiconductor substrate, and a cavity arrangement including at least one cavity in spatial proximity to the respective memory element. The cavity is in spatial arrangement with the respective memory element so as to reduce thermal coupling of the respective memory element to the areas surrounding the memory element, which also reduces the thermal conductivity between memory element and the areas surrounding the memory element.

### CROSS REFERENCE TO RELATED APPLICATIONS

This application is a continuation of International Patent Application No. PCT/DE2003/003885, filed on Nov. 24, 2003, and titled “Semiconductor Memory Device and Method For Producing It,” and further claims priority under 35 USC § 119 to German Application No. DE 102 55 117.0, filed on Nov. 26, 2002, and titled “Semiconductor Memory Device and Method For Producing It.” The entire contents of each of the above-identified patent applications are hereby incorporated by reference.

### FIELD OF THE INVENTION

The present invention relates to a semiconductor memory device and a method for producing the device.

### BACKGROUND OF THE INVENTION

Memory designs are continuously being introduced in the ongoing development of modern semiconductor memory technologies. These designs relate in particular to nonvolatile memories. In particular, the memory media to be provided in the respective memory cells or memory elements are selected and used with regard to their physical properties during phase transformations. Thus, by way of example, nonvolatile memories are known in which the memory medium undergoes a transition during a phase transformation from a low-resistance (if appropriate crystalline) state to a high-resistance (if appropriate amorphous) state. This design thus makes use of a material as a memory medium that has two stable phases, namely a high-resistance amorphous phase and a low-resistance crystalline phase. The material can be switched back and forth reversibly with regard to these two phases by electrical pulses. The corresponding changes in resistance during the phase transition between the amorphous phase and the crystalline phase are used for information storage. Although so-called chalcogenides have customarily been used heretofore for this purpose, in principle any material that permits a reversible changeover between a high-resistance and a low-resistance state is suitable as memory medium in these nonvolatile memories.

What is problematic about known semiconductor memory technologies based on a phase transformation memory effect is that a specific quantity of heat must be fed to the respective memory cell or to the respective memory element in order to initiate and carry out the phase transformation. In this case, the quantity of heat supplied has to be prevented from also influencing adjacent cells or elements and changing the information state thereof. This has been realized heretofore by complying with a specific minimum distance between adjacent memory cells or elements in a semiconductor memory device with a phase transformation memory effect. However, complying with such a minimum distance between two adjacent memory cells or memory elements goes against endeavors to provide a highest possible integration density for semiconductor memory devices.

### SUMMARY

An object of the present invention is to provide a semiconductor memory device based on a phase transformation memory effect material and also a method for producing the device by which semiconductor memory devices with a phase transformation memory effect can be realized with a particularly high integration density and nevertheless a high functional reliability.

The aforesaid and further objects are achieved individually and/or in combination, and it is not intended that the present invention be construed as requiring two or more of the objects to be combined unless expressly required by the claims attached hereto.

In accordance with the present invention, a semiconductor memory device includes at least one memory element with a phase transformation memory effect and a cavity arrangement with at least one cavity in spatial proximity to the respective memory element in such a way that the thermal coupling of the respective memory element to the surroundings of the memory element is formed in reduced fashion by reduction of the thermal conductivity between memory element and surroundings.

Consequently, a fundamental idea of the present invention is to provide a cavity arrangement with at least one cavity in the semiconductor substrate in which the memory element is formed. The respective cavity avoids providing a material which has a specific residual thermal conductivity. The cavity, whether evacuated or filled with gas, in any event always has a lower thermal conductivity than a material region formed in a corresponding manner, so that the thermal coupling between the memory cell and its surroundings, namely the semiconductor substrate or an adjacent element, is reduced.

A particularly advantageous embodiment of the semiconductor memory device according to the invention results when, for the memory element in the semiconductor substrate, a first or bottom access electrode device is provided, a second or top access electrode device is provided and also a memory medium is formed at least partly in between with a phase-dependent nonreactive resistance in a manner contact-connected to the access electrodes. At least one of the access electrode devices, preferably the first or bottom access electrode device, is provided and formed as an excitation electrode or heating electrode for locally heating the contact-connected memory medium and thus for initiating a corresponding phase transformation process or a corresponding phase transformation.

At least a part of the cavity arrangement, in particular at least one cavity, is provided in spatial proximity to the excitation electrode and/or in spatial proximity to the memory medium for the purpose of thermal insulation from the surroundings. As a result, in particular that element which carries the greatest part of the heat and is thus most likely to have a high temperature, namely that electrode which is designed for heating the memory medium and thus for exciting the phase transformation process, is thermally insulated from the surroundings by the cavity, so that a transfer of heat to the surroundings, and in particular to adjacent memory elements that are not selected, is at least reduced.

In another embodiment of the semiconductor memory device according to the invention, the excitation electrode in each case is assigned a cavity of the cavity arrangement, and the assigned cavity is directly adjoined to at least a part of the excitation electrode. In this embodiment, it is preferred for the assigned cavity to surround at least a part of the excitation electrode. This is because the thermal insulation from the surroundings and from adjacent memory elements is then particularly effective.

In yet another embodiment of the semiconductor memory device according to the invention, the excitation electrode is formed as a connecting region or plug region or as part thereof with respect to a source/drain region of a provided and assigned selection transistor, preferably a lateral selection transistor. This results in a particularly compact design of the semiconductor memory device according to the invention because, in the formation of the respective memory element, there is no need for an additional contact, terminal or plug between the source/drain region of the selection transistor and the respective first or bottom electrode.

In a further embodiment of the semiconductor memory device according to the invention, the excitation electrode is formed in a cutout or a trench structure or a trench, to be precise in the semiconductor substrate underlying the semiconductor memory device.

In another embodiment of the semiconductor memory device according to the invention, the memory medium is formed as a material region of the excitation electrode, preferably in an upper region of the trench structure. This embodiment is particularly space-saving because the memory medium with a phase transformation memory effect is also simultaneously formed in the connection region or plug region—serving as excitation electrode—toward the source/drain region of the selection transistor. This is realized in particular by filling an upper part of the respectively underlying trench structure.

A plurality of memory elements can be provided in the semiconductor memory device according to the invention. In this embodiment, it is advantageous to form a common memory region with a phase transformation memory effect for the plurality of memory elements. Alternatively, it is possible to form individual memory regions for the plurality of memory elements. It is preferable, however, if in each case two memory elements which are formed adjacent to one another in the semiconductor substrate jointly utilize a memory region.

In an embodient where a memory region is jointly utilized by a plurality of memory elements, the cavity arrangement, and in particular the respective cavity or the respective cavities, is at least partly formed laterally between the plurality of memory elements. In this embodiment, the respective cavity arrangement or the respective cavity is then jointly used by a plurality of memory cells. The joint utilization of cavity and memory medium may also be combined with one another in order to achieve a particularly compact configuration of the semiconductor memory device according to the invention.

Furthermore, it is advantageous and, moreover, increases the integration density of the semiconductor memory device according to the invention when a common further or second access electrode device is provided for a plurality of memory elements. In specific applications, however, it may also be advantageous for individual further or second access electrode devices to be formed or provided for the plurality of memory elements.

A method for producing a semiconductor memory device in accordance with the present invention and including at least one memory element with a phase transformation memory effect by providing a cavity arrangement with at least one cavity in spatial proximity to the respective memory element in such a way that the thermal coupling of the respective memory element to the surroundings of the memory element is formed in reduced fashion by reduction of the thermal conductivity between memory element and surroundings.

In a preferred embodiment of the method according to the invention, for the at least one memory element in the semiconductor substrate, a first or bottom access electrode device is provided, a second or top access electrode device is provided and a memory medium is formed at least partly in between with a phase-dependent nonreactive resistance in a manner contact-connected to the access electrode devices. At least one of the access electrode devices, preferably the first or bottom access electrode device, is provided and formed as an excitation electrode for locally heating the contact-connected memory medium and thus for initiating a corresponding phase transformation process or a corresponding phase transformation. At least a part of the cavity arrangement and in particular at least one cavity is provided in spatial proximity to the excitation electrode and/or the memory medium for the purpose of thermal insulation from the surroundings. In this embodiment, the excitation electrode is in each case assigned a cavity of the cavity arrangement, in such a way that the assigned cavity directly adjoins at least a part of the excitation electrode. In this embodiment, it is also preferred that the assigned cavity is formed in a manner surrounding at least a part of the excitation electrode.

In another embodiment of the method according to the invention, the excitation electrode is formed as a connecting region or plug region or as part thereof with respect to a source/drain region of a provided and assigned selection transistor, in particular a lateral selection transistor.

In accordance with a further embodiment of the method according to the invention, the excitation electrode is formed in a cutout or a trench structure in the semiconductor substrate.

The memory medium itself may be formed as a material region of the excitation electrode, in particular in an upper region of the respective trench structure.

It is particularly advantageous to provide a plurality (e.g., two) of memory elements, and the plurality of memory elements are formed with a common memory region. Alternatively, individual memory regions or memory media in each case can be formed for the plurality of memory elements. It is preferred that the cavity arrangement, and in particular the respective cavities, is at least partly formed laterally between the plurality of memory elements or memory cells. It is also preferred that a common further or second access electrode device is formed for the plurality of memory cells or memory elements. As an alternative, individual further or second access electrode devices are also conceivable for the plurality of memory elements or memory cells.

In a further embodiment of the method according to the invention, the cavity arrangement and the respective cavities are lined with a thin layer made of SiO₂ or BPSG on the inside.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIGS. 1-15 depict sectional side views in schematic of intermediate states of the semiconductor memory device that are attained in accordance with the invention.

FIGS. 16-24, 27 and 30-32 depict sectional side views in schematic of intermediate states of the semiconductor memory device that are attained in accordance with the invention.

FIGS. 25 and 28 depict sectional side views in schematic taken along lines B-B′ of FIGS. 26 and 29, respectively, of intermediate states of the semiconductor memory device attained in accordance with the invention.

FIGS. 26 and 29 depict plan views in schematic of intermediate states of the semiconductor memory device that are attained in accordance with the invention.

FIGS. 33-35 depict sectional side views in schematic of three further embodiments of the semiconductor memory device according to the invention.

### DETAILED DESCRIPTION

A series of designs, such as ferroelectric memories, magnetoresistive memories, and also phase transformation memories are being discussed for future nonvolatile memories.

In the case of phase transformation memories, the information is represented as a crystalline or amorphous state of a vitreous material. In this case, the phase transformation is effected by heating the material via a suitable electrical pulse. Chalcogenides GeₓSb_{y}—Te_{z}, InSbTe, AgInSbTe and the like are used as preferred materials. The material utilized most often, Ge₂Sb₂Te₅, requires, e.g., approximately 310° C. for crystallization and approximately 600° C. for melting and thus for converting the material from the crystalline phase to the amorphous phase.

One problem consists in the fact that even when heating the material to 600° C., an adjacent cell must not become so hot that it changes its state. This problem at the present time limits the scalability and integration density of phase transformation memories.

According to present-day estimations, the limit of the scalability and integration density of phase transformation memories occurs at minimum feature sizes of approximately 70 nm due to the influencing of an adjacent bit in the case of erasure. Conventional integration routes could still be taken in the case of the minimum feature sizes of 180 nm and 130 nm that are currently being discussed. Insulation materials having a much lower thermal conductivity than silicon dioxide, which has been used heretofore, are currently being discussed for the 70 nm generation and beyond.

Silicon dioxide has a thermal conductivity of 0.014 W/cm K. In comparison therewith, the preferred material class for phase transformation materials is 0.003-0.18 W/cm K. The preferred material composition at the present time, Ge₂Sb₂Te₅, has a value of 0.0046 W/cm K, so that a large part of the heat is dissipated by the insulation material in this case. An improvement would result, for example, by using polyimide having a thermal conductivity of 0.0016 W/cm K. However, this cannot readily be integrated into a CMOS process sequence at the required point.

The invention solves this problem by separating the individual cells from one another via cavities. This has the effect that the thermal conductivity between the cells becomes minimal.

One feature of the invention resides in separating the individual cells from the surroundings and respectively from one another indirectly or directly via cavities, to be precise both structurally and by a suitable process implementation.

A number of embodiments of the invention are described below. In one embodiment, a suitable sacrificial layer is removed about the heating element. This has the effect that the heater or the excitation electrode is thermally insulated from the surroundings.

In another embodiment, the activated region is additionally insulated from the surroundings by concomitantly introducing it into the opening for the heating electrode. In a further embodiment, the heating elements are encapsulated in etching stop layers, and the insulation material is subsequently removed between the structures. In this embodiment, it is possible for the phase transformation material itself to be integrated into the cutout for the heating element.

In an additional embodiment, the sacrificial layer or the spacer can be applied and patterned lithographically such that they project significantly beyond the contact hole. Thus, prior to the application of the metallization, an opening may be etched as far as the sacrificial layer and the latter may be wet-chemically removed selectively with respect to the surroundings. This has the effect that the structure is insulated toward the bottom in the direct surroundings as well.

A further embodiment, in relation to all the previously described structures, inludes applying a further very thin layer (e.g., an SiO₂ that is 5-10 nm thick) between the cavity and the heating electrode material or heating electrode material and chalcogenide by the known spacer technique. This has the effect, when etching the sacrificial layer and the heating electrode material, of preventing the latter from being attacked by the etching.

Further features for reducing the thermal coupling includes using an SOI substrate (heat flow via the silicon is prevented) and in introducing an additional thermal insulation between chalcogenide and top electrode, and in producing the contact only at the edge, e.g. by spacers or overlap, or at individual locations by contacts.

Embodiments of the invention are now described with reference to the figures, where structurally or functionally similar or identical elements or material regions are designated by the same reference symbols hereinafter without a detailed discussion of their properties being repeated upon every occurrence in the description or in the figures.

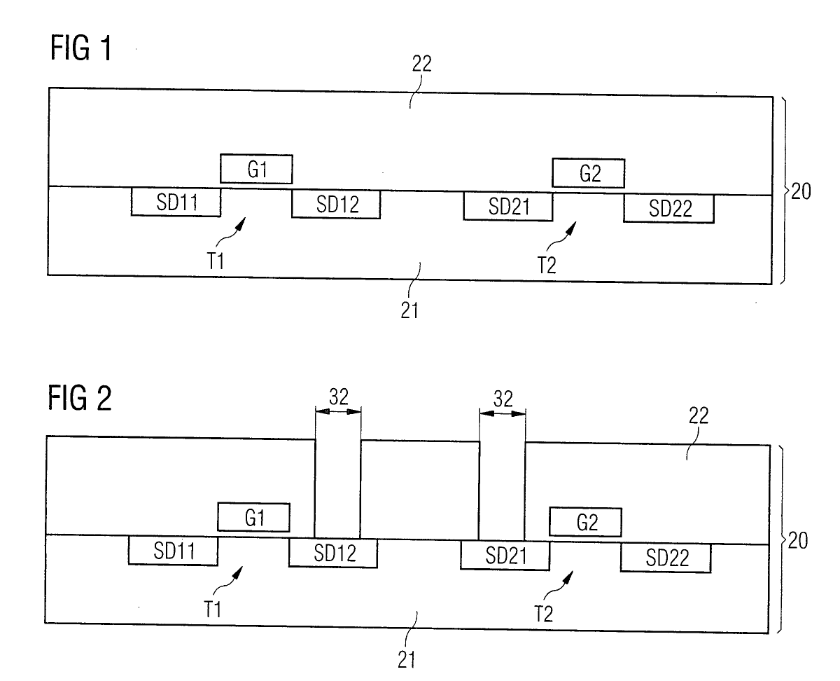

FIG. 1 shows, in schematic and sectional side view, a semiconductor substrate 20, including a first material region 21 and a second material region 22, the latter having electrically insulating properties. A CMOS structure is formed in said semiconductor material region 20, said CMOS structure having selection transistors T1 and T2, for example, which, for their part, have first source/drain regions SD11 and SD21, respectively, second source/drain regions SD12 and SD22, respectively, and also gate regions G1 and G2.

In the transition to the intermediate state of FIG. 2, trenches or trench structures 32 are formed in a standard manner above the adjacent source/drain regions SD12 and SD21 of the first and second selection transistors T1 and T2. Said trenches or trench structures are also referred to as contact holes.

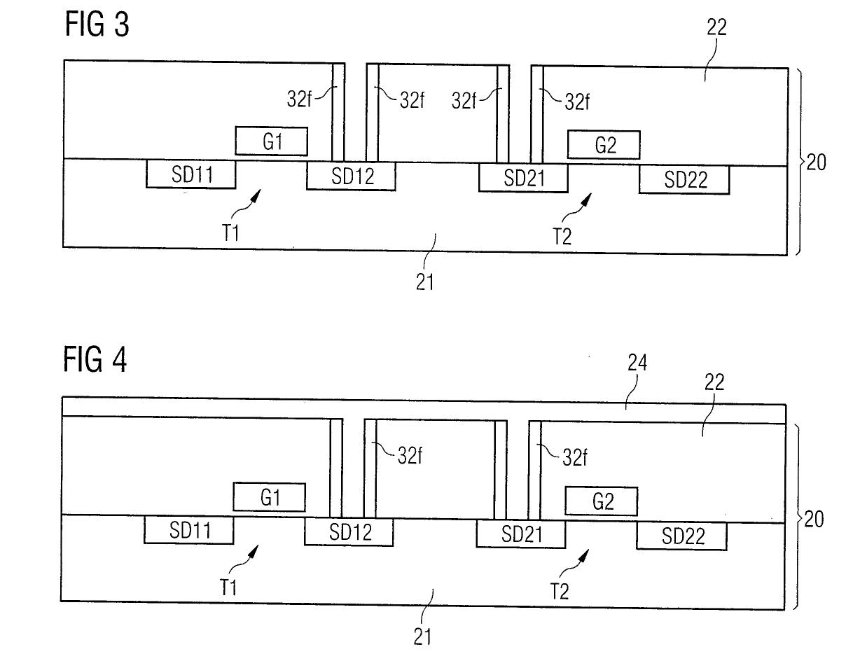

In the transition to the intermediate state of FIG. 3, spacers 32f are formed in the trench structures 32, so that wall regions of the trench structures 32 are covered but at least a part of the bottom regions of the trench structures 32 remains free. The free diameter of the trench structure 32 is thereby constricted. Said spacers 32f are produced by conformal deposition of a material region, for example a dielectric or an insulation material—here namely in the form of a sacrificial layer that can be etched selectively with respect to the electrode material which is deposited later—and subsequent etching back of the laterally extending material regions, so that only the perpendicular material regions in the form of the spacers 32f remain in the trench structure 32.

In the transition to the intermediate state of FIG. 4, a layer 24 of a suitable electrode material is deposited.

In the transition to the state of FIG. 5, the lateral region of the material layer 24 is removed by CMP with a stop at the level of the first or bottom electrodes 14-1, 14-2.

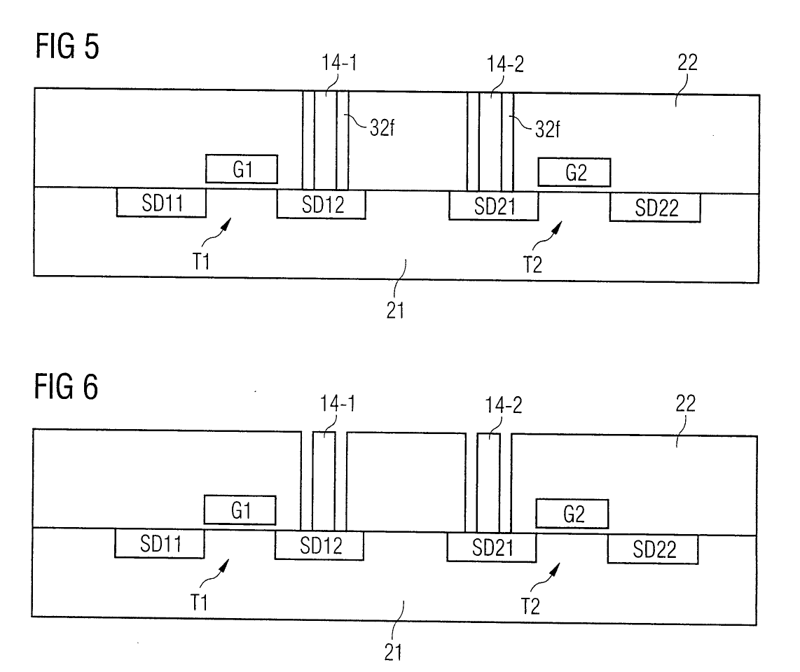

In the transition to the state of FIG. 6, the spacer material 32f is removed selectively from the trench structures 32, so that exclusively the first or bottom electrodes 14-1 and 14-2 remain in pillarlike fashion in the trench structures 32.

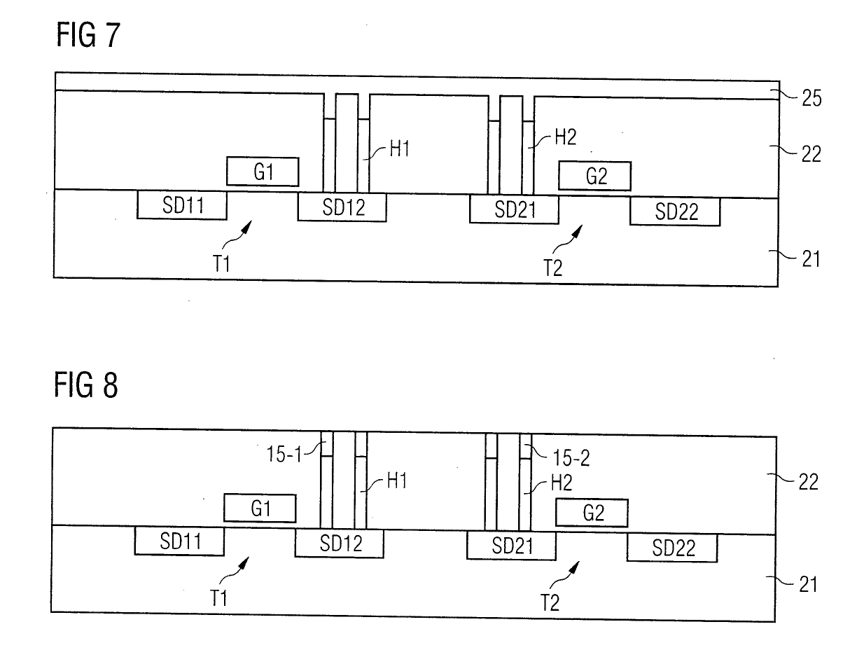

In the transition to the state of FIG. 7, a material layer 25 is then deposited, the material of which has a very poor edge coverage. This has the effect that the trench structures 32 with the first electrodes 14-1 and 14-2 situated therein are not completely filled, to be precise in such a way that cavities H1 and H2 remain, which form the so-called cavity structure H of the invention.

As an alternative, the cavities H1, H2 can be closed off by deposition and subsequent flowing of a BPSG layer. This alternative has the advantage that the inner walls of the cavities H1, H2 are then lined with BPSG.

In the transition to the state of FIG. 8, planarization is effected by CMP with a stop at the topmost level of the first access electrode devices 14-1 and 14-2 and the lateral portion of the material layer 25 is removed, so that only plug elements 15-1 and 15-2 remain above the cavities H1 and H2.

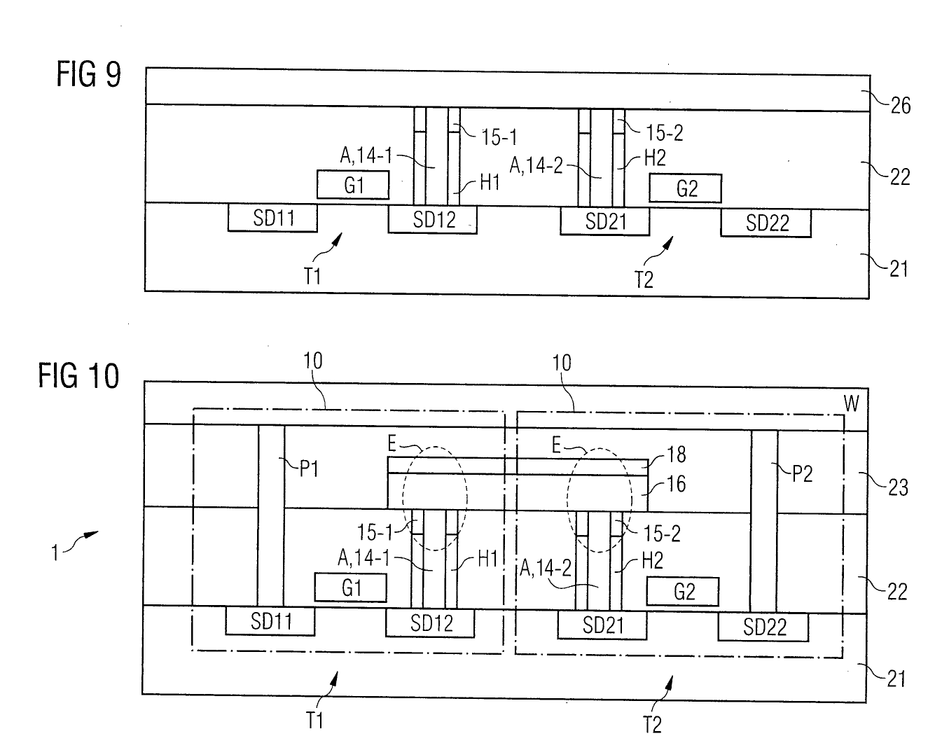

A layer 26 of a material with a phase transformation nature is then deposited, as is illustrated by the state of FIG. 9.

In the transition to the state of FIG. 10, an embodiment of the semiconductor memory device according to the invention is completed in that firstly the phase transformation material 26 is patterned and covered with a second or top access electrode device 18. So-called contact-connecting or plug regions P1 and P2 to the outer source/drain regions SD11 and SD22, respectively, are additionally formed. The entire structure is embedded in an insulation region 23 and covered with a metallization layer W for making contact with the plug regions P1 and P2. The memory elements E are formed by the two access electrode devices 14 and 18, the bottom electrodes 14 in this case forming the excitation or heating electrode, and the region 16 of the phase transformation material that is provided in between. The memory cells 10 are then evident (shown in dashed lines in FIG. 10) by adding the access transistors T1, T2 to the respective memory element E.

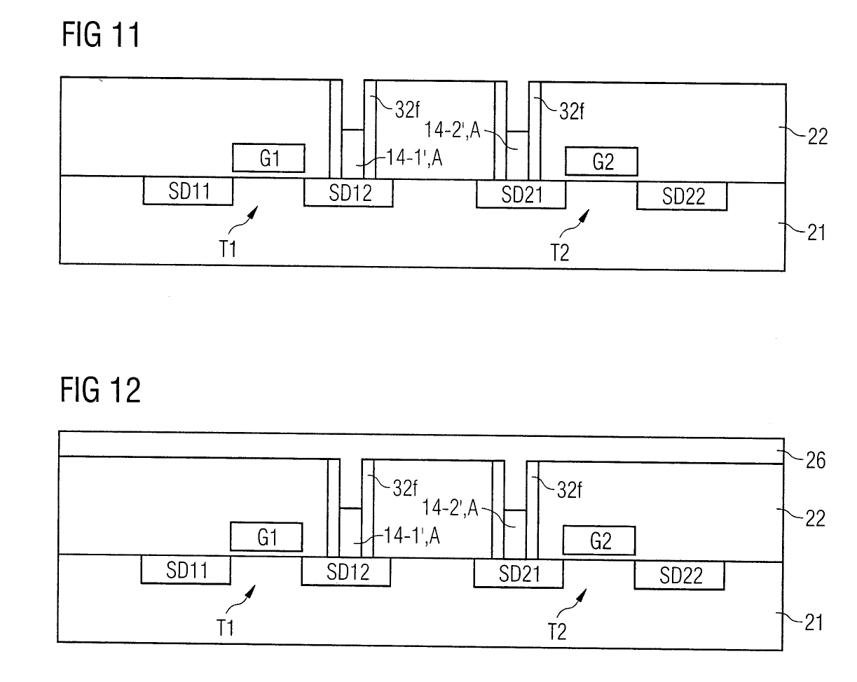

Another variation of the production method according to the invention proceeds from the structure illustrated in FIG. 5 and, in the transition to the intermediate state shown in FIG. 11, performs an etching-back process on the first or bottom access electrode devices 14-1 and 14-2 in order to obtain reduced first or bottom access electrode devices 14-1′ and 14-2′. In the transition to the structure in FIG. 12, the phase transformation material is then deposited in the form of a layer 26.

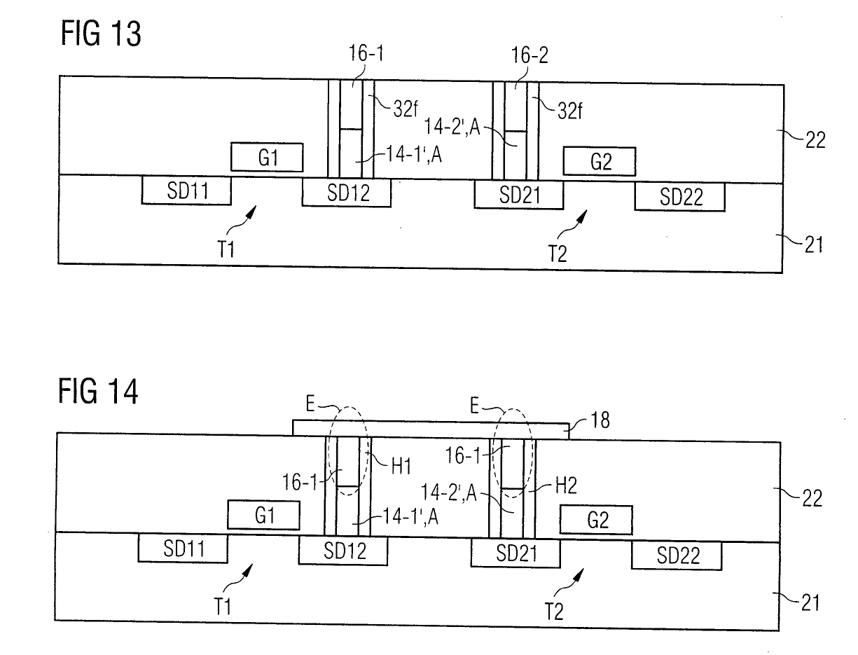

In the transition to the intermediate state shown in FIG. 13, planarization is then effected by a CMP method, so that the lateral layer regions of the layer 26 are removed from the surface of the substrate region 22. As a result, in the region of the trench structure 32, regions of the memory medium 16, namely the regions 16-1 and 16-2, arise as a geometrical continuation of the first or bottom access electrode devices 14-1′ and 14-2′. In other words, regions 16-1 and 16-2 are adjacent and extend above electrode devices 14-1′ and 14-2′ within trench structures 32.

In the transition to the state of FIG. 14, the spacer elements 32f are then etched out selectively, thereby forming the cavities H1 and H2 which virtually surround the first or bottom access electrode devices 14-1′ and 14-2′ and also the memory media 16-1 and 16-2 and form the cavity arrangement H in the accordance with the invention. The counterelectrode in the form of the second or top access electrode device 18 is additionally formed, which is a common access electrode for the two memory elements E illustrated.

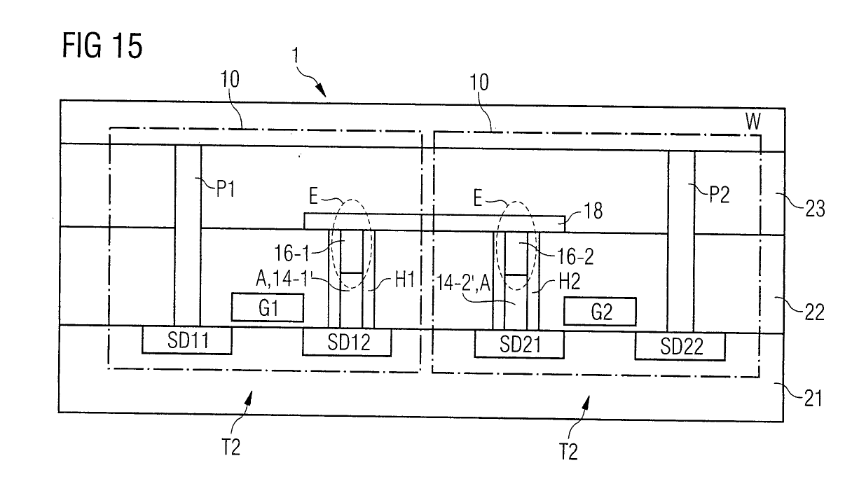

The transition to the state of FIG. 15 is then effected by embedding in an insulation or dielectric region 23, the formation of contact-making plug regions P1 and P2 and also a covering with a metallization layer W.

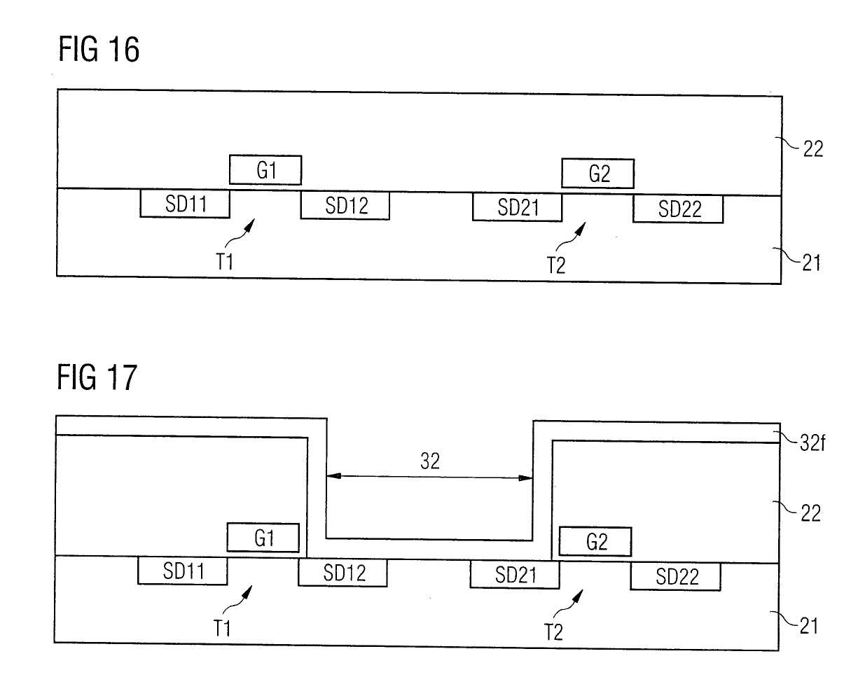

Another variation of the production method according to the invention begins with an arrangement which corresponds to the arrangement of FIG. 1 and which is illustrated again in FIG. 16.

In the transition to the state of FIG. 17, instead of the formation of narrow trench structures between the gates G1 and G2 of adjacent selection transistors T1 and T2, now a comparatively wide cutout or trench structure 32 is formed and subsequently lined with a thin etching stop layer 32f, e.g. made of silicon nitride or the like.

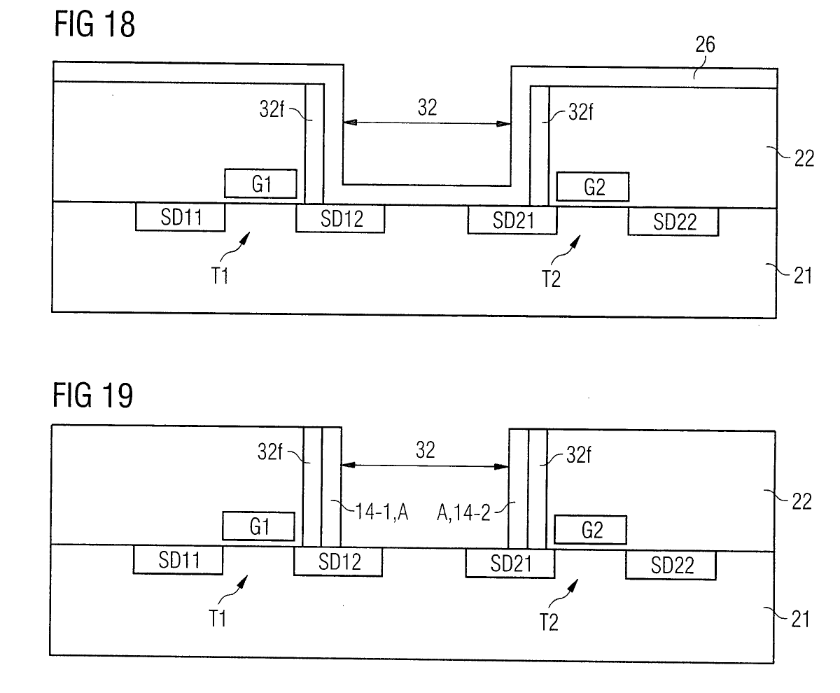

In the transition to the state of FIG. 18, the etching stop layer 32f is then etched back, so that lateral regions thereof are removed and only the spacers 32f remain on the sidewalls of the trench structure 32. In addition, a suitable electrode material is then deposited in the form of a layer 26.

In the transition to the state of FIG. 19, the layer 26 of the electrode material is then likewise etched back, so that the pillars of the first or bottom access electrode devices 14-1 and 14-2 still remain alongside the spacers 32f.

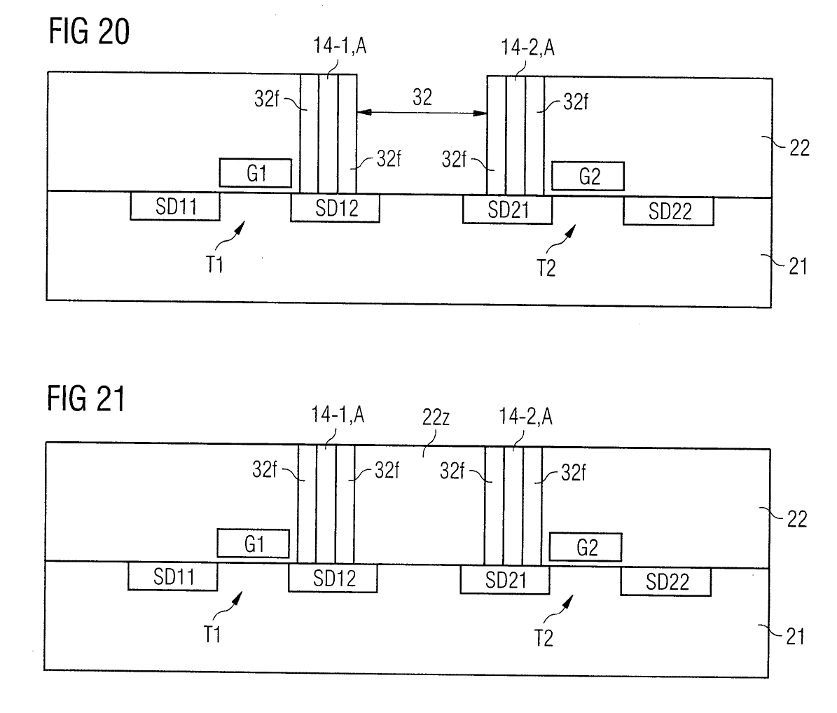

In the transition to the state of FIG. 20, a further etching stop layer is then optionally deposited and etched back, thereby forming in each case inner spacer elements 32f which further constrict the trench structure 32.

In the transition to the state of FIG. 21, the remaining trench structure 32 is then filled with an insulation layer 22z, e.g. made of oxide or BPSG, if appropriate with the use of a planarization method by CMP.

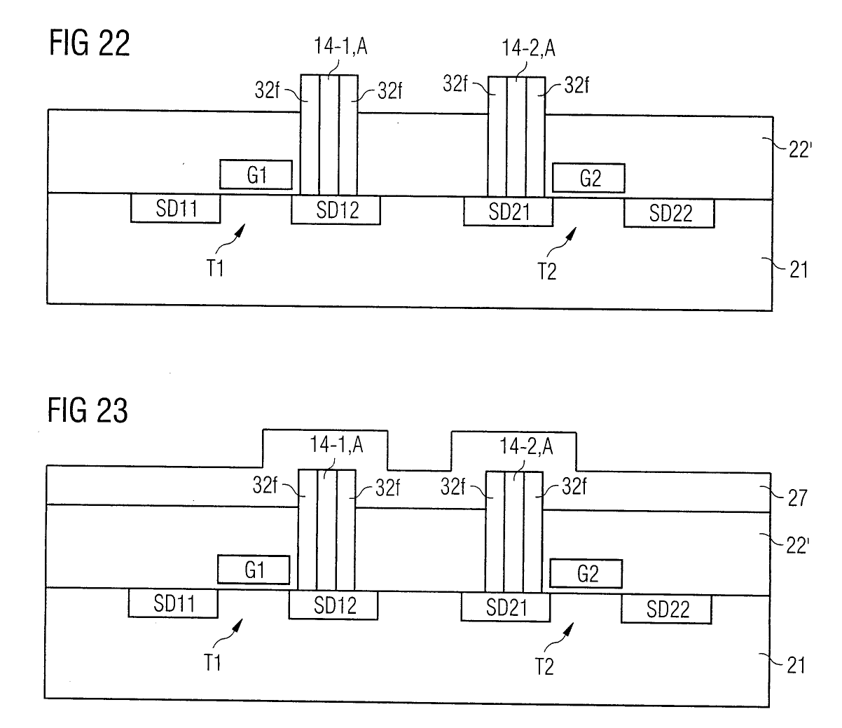

In the transition to the state of FIG. 22, the insulation layers 22 and 22z are then etched back to form reduced or diminished insulation layers 22′, so that the first or bottom access electrode devices 14-1 and 14-2 and also the etching stop layers in the form of the spacers 32f project from the surface of the diminished insulation layer 22′.

In the transition to the state of FIG. 23, a further etching stop layer 27 is then formed, e.g. made of silicon nitride or the like, which covers and embeds the first or bottom access electrode devices 14-1 and 14-2 and also the spacers 32f.

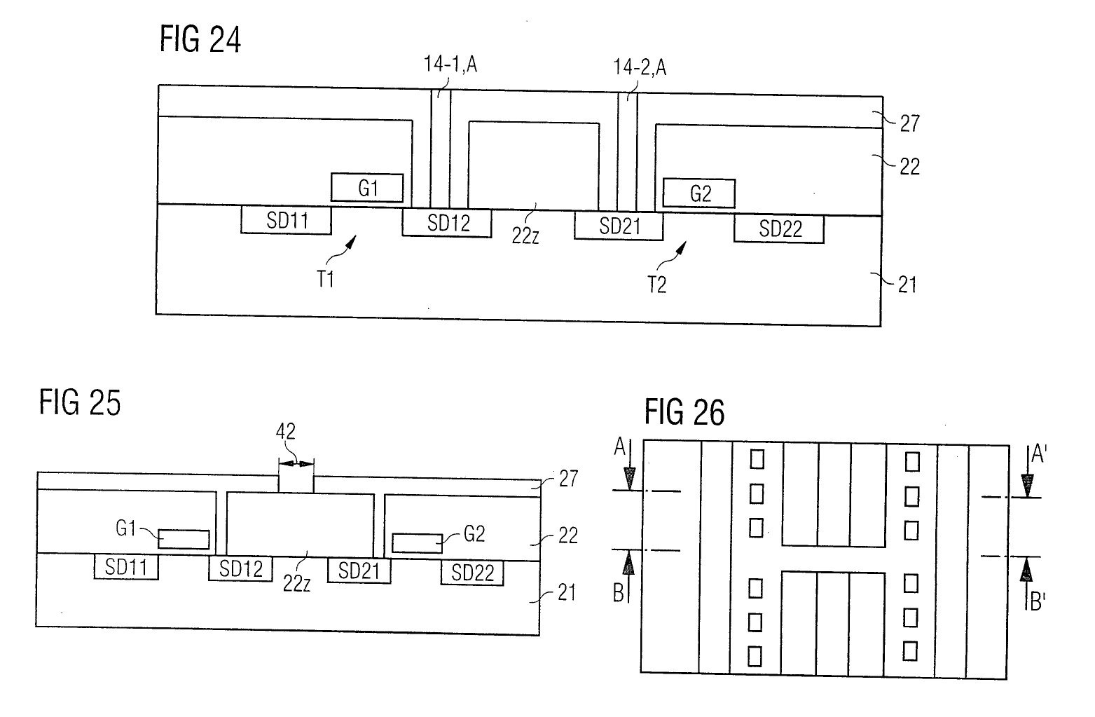

In the transition to the state of FIG. 24, planarization is then effected by CMP, to be precise with a stop at the level of the first or bottom access electrode devices 14-1 and 14-2.

The etching stop layer 27 is then opened between two cells, as is indicated by the cutout 42 in FIG. 25, where FIG. 25 is a view of the device in the section along the line B-B′ of FIG. 26 (which shows a plan view of the device).

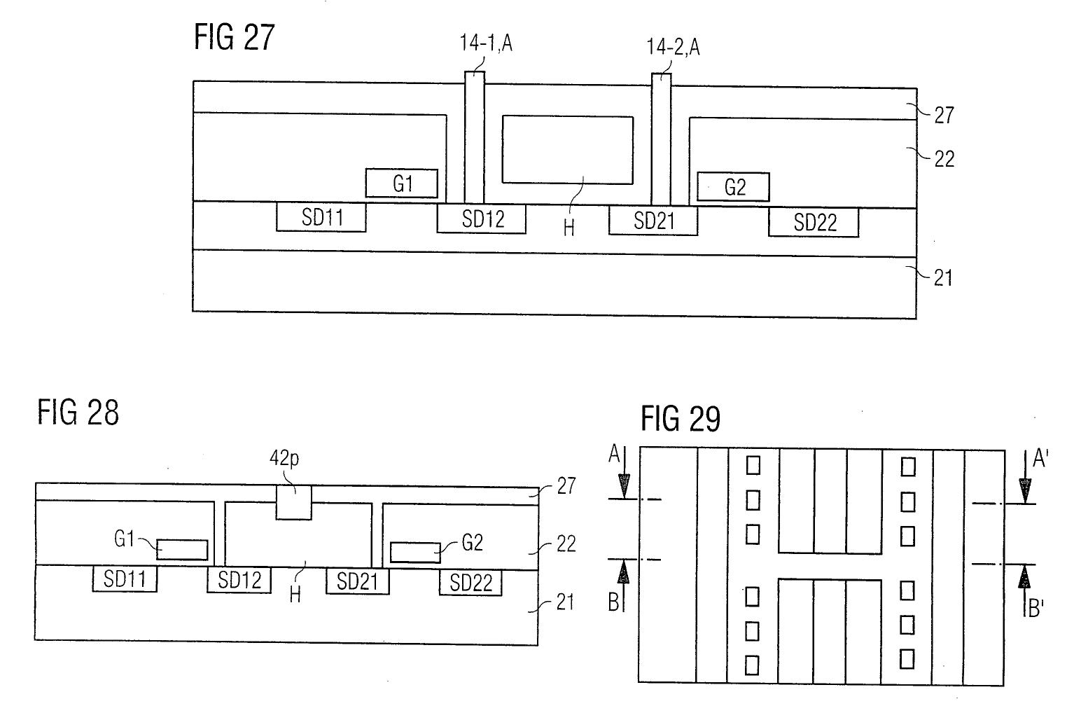

In the transition to the state of FIGS. 25 to 27, then, firstly the insulation material of the region 22z is removed by etching selectively with respect to the etching stop layer through the opening hole 42, as a result of which a cavity H arises between the two bottom or first access electrode devices 14-1 and 14-2. Afterward, an insulation layer with poor edge coverage is then deposited in order to close off the opening hole 42 and consequently the cavity H by a plug 42p. The plug 42p is shown in FIG. 28, which is a view of the device in the section along the line B-B′ of FIG. 29 (which shows a plan view of the device).

As an alternative, the cavities H1, H2 may be closed off by deposition and subsequent flowing of a BPSG layer. This variant has the advantage that the inner walls of the cavities H1, H2 are then lined with BPSG.

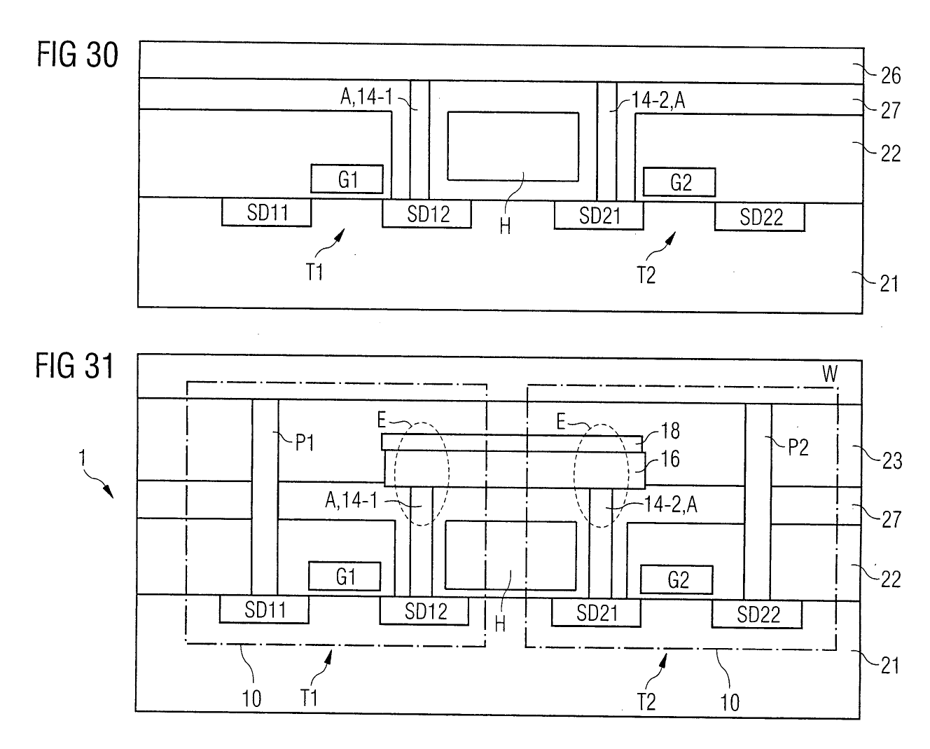

In the transition to the state of FIG. 30, a layer 26 of the phase transformation material is then once again deposited.

The transition to the state of FIG. 31 is then effected by the patterning of the memory material 16 from the material layer 26 of the phase transformation material, the covering and patterning with the common second or top access electrode device 18, the embedding in an insulation region 23, the formation of the plugs P1 and P2 for contact-connection of the outer source/drain regions SD11 and SD22, of the selection transistors T1 and T2 and also a connection of the plug regions P1 and P2 by a metallization region W.

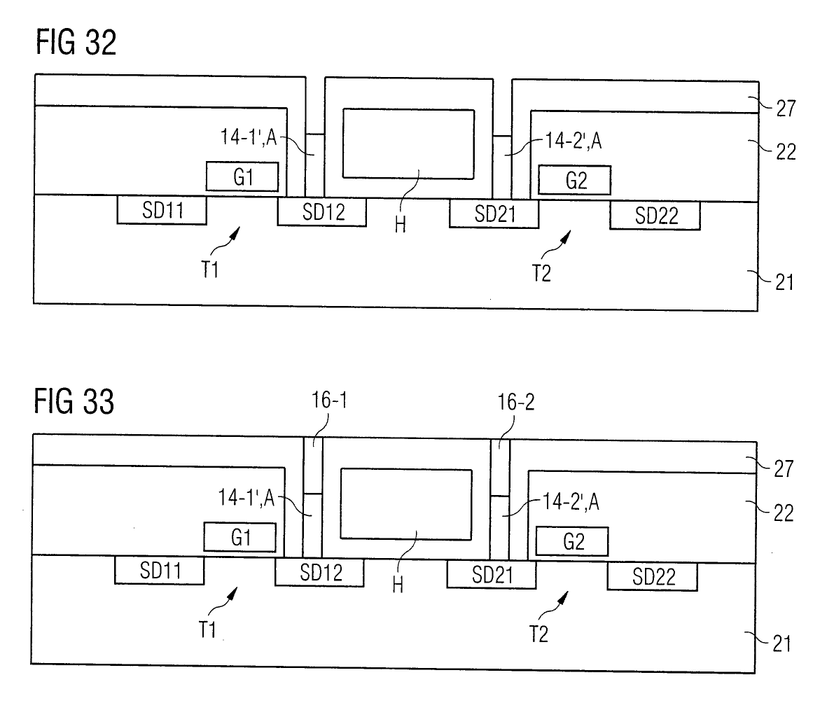

In an alternative embodiment, proceeding from the intermediate state of FIG. 24 with a cavity H already having been formed, the first or bottom access electrode devices 14-1 and 14-2 formed are etched back in order to obtain reduced or diminished first or bottom access electrode devices 14-1′ and 14-2′, as is illustrated in FIG. 32.

In the transition to the state of FIG. 33, the phase transformation material is then once again deposited and removed by a CMP method, so that exclusively material regions 16-1 and 16-2 remain individually for the first or bottom access electrode devices 14-1 and 14-2 within the etched-back regions of said electrodes 14-1 and 14-2.

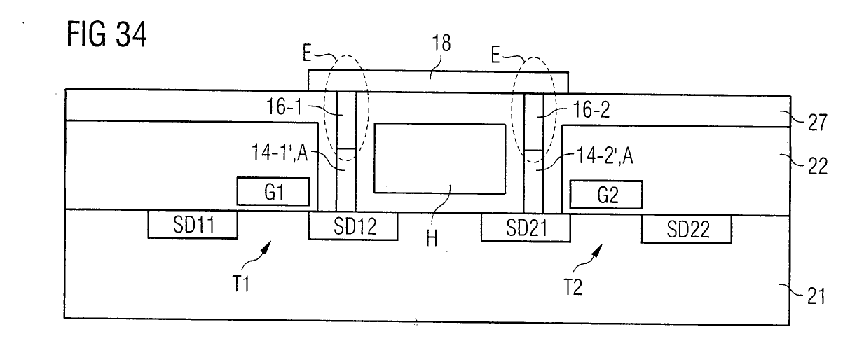

In the transition to the state of FIG. 34, the common second or bottom access electrode device 18 is then formed.

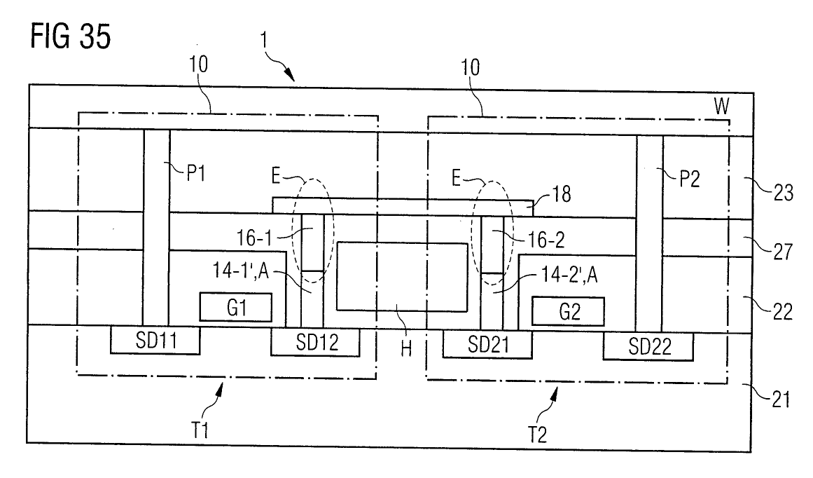

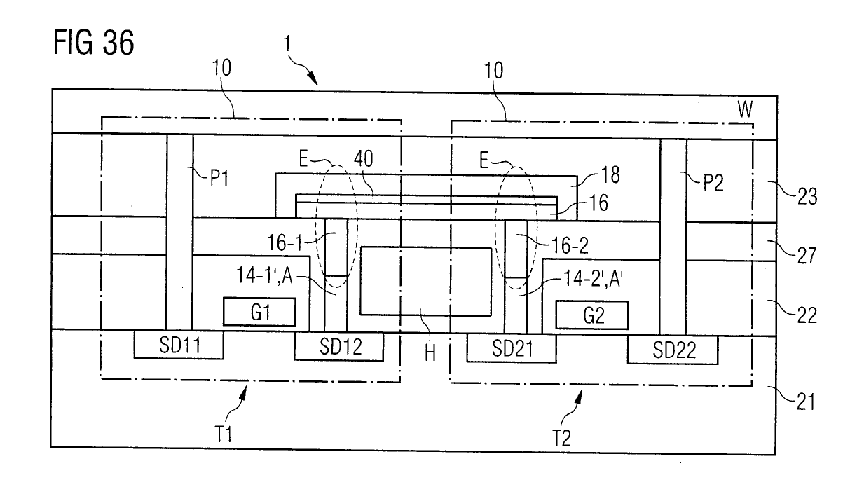

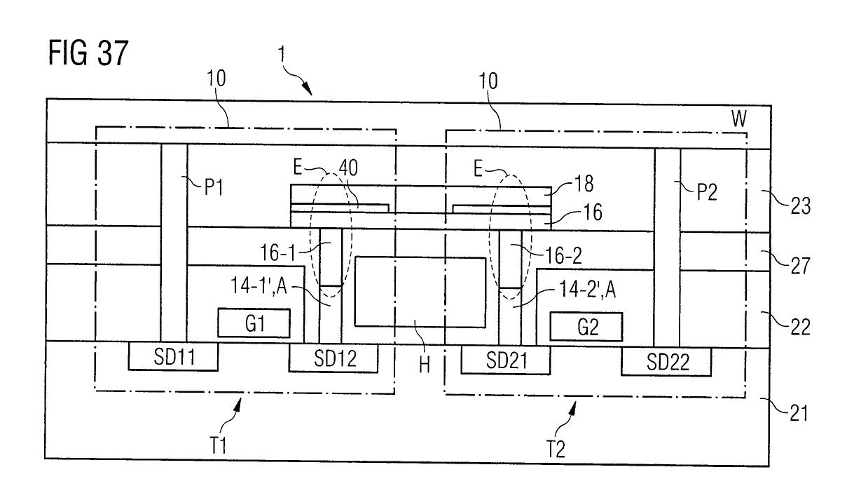

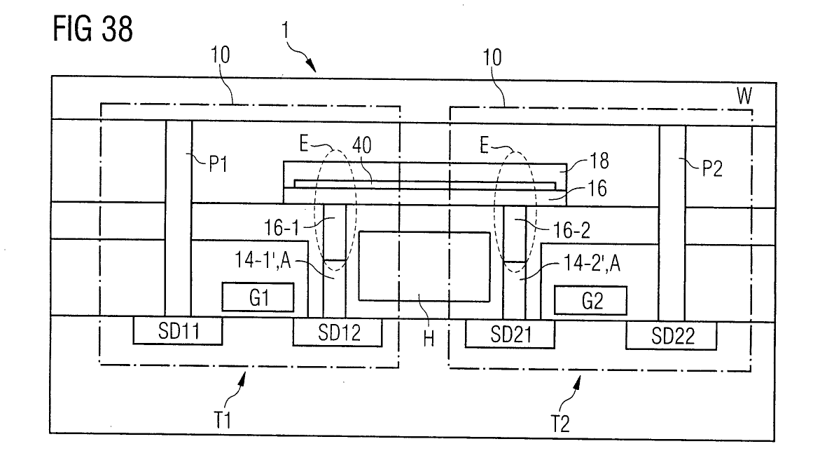

The transition to the state of FIG. 35 is then effected by the customary completion by embedding in an insulation region 23, formation of the plug regions P1 and P2 for the connection of the outer source/drain regions SD11 and SD22 of the adjacent selection transitions T1, T2 and also the contact-connection or connection of the plug regions P1 and P2 by a metallization layer W.

Proceeding from the arrangement illustrated in FIG. 35, there are still further additional possibilities for improving the thermal insulation of adjacent memory elements E or memory cells 10. In this embodiment, it must first of all be emphasized that the memory cells 10 are essentially defined by the access or selection transistors T1 and T2. The cells 10 are firstly essentially thermally insulated from one another by the cavity H formed.

In the embodiment of FIG. 36, a thermal insulator 40, including BPSG or polyimide for example, is additionally provided between the phase transformation material 16 and the second or top access electrode device 18. For this purpose, the second or top access electrode device 18 is drawn around the phase transformation material 16.

In the embodiment of FIG. 37, a thermal insulator 40 is likewise provided between the phase transformation material 16 and the second or top access electrode device 18, but a contact-connection of the second or top access electrode device 18 to the phase transformation material 16 is realized in the center through a contact hole.

In the embodiment of FIG. 38, by contrast, an access takes place at the edges of the layer structure comprising memory medium 16 or phase transformation material 16, thermal insulator 40 and second or top access electrode device 18.

All of the structures described previously can be formed with the material combinations listed below. The first semiconductor material substrate region 21 of the semiconductor substrate 20 may include p-type silicon, by way of example. The source/drain regions SD11, SD12, SD21, SD22 can then correspondingly include n⁺-type silicon. The conductivity types or conduction types can also be interchanged. The gates G1 and G2 can be fabricated from polysilicon, polycide, salicide or from a suitable material. Examples of appropriate insulation materials, in particular for the regions 22 and 23, are silicon dioxide, silicon oxynitride, BPSG or the like. Etching stop materials for the spacers 32f can be formed for example from silicon nitride, from aluminum oxide or the like. The material for the first or bottom access electrode devices 14, 14-1, 14-2, 14-1′, 14-2′, that is to say for the excitation electrode, which may also be referred to as a heating electrode, may appropriately be tantalum nitride, titanium silicon nitride, titanium nitride, titanium aluminum nitride, titanium silicon nitride, carbon, molybdenum, tungsten, titanium-tungsten and the like.

The material of the counterelectrode, that is to say of the second or top access electrode devices 18, may be aluminum, copper, tungsten, silicide or the like.

The plugs P1 and P2 can include tungsten, polysilicon, copper or aluminum. The metallizations for the interconnects W can include for example aluminum and copper. The thermal insulator 40 can include for example BPSG, polyimide or the like.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1 Semiconductor memory device
10 Memory cell
14 First access electrode device, bottom access electrode device, bottom electrode, heating electrode
14-1 First access electrode device, bottom access electrode device, bottom electrode, heating electrode
14-1′ First access electrode device, bottom access electrode device, bottom electrode, heating electrode
14-2 First access electrode device, bottom access electrode device, bottom electrode, heating electrode
14-2′ First access electrode device, bottom access electrode device, bottom electrode, heating electrode
16 Memory medium, phase transformation material
16-1 Memory medium, phase transformation material
16-2 Memory medium, phase transformation material
18 Counterelectrode, second access electrode device, top access electrode device, top electrode
20 Semiconductor substrate
21 First substrate region, first material region
22 Second substrate region, second material region, insulation region
22z Insulation region
22′ Reduced or pulled-back insulation region
23 Insulation region
24 Material for the first access electrode device 14
25 Material region for phase transformation material or memory medium
26 Material region for the memory medium 16
27 Etching stop layer
32 Cutout, trench, trench structure
32f Etching stop layer, spacer
40 Thermal insulator
42 Cutout
42p Contact plug
H, Cavity
H1, H2 Cavities
G1, G2 Gate regions
SD11 Source/drain region
SD12 Source/drain region
SD21 Source/drain region
SD22 Source/drain region
P1, P2 Plug regions
W Metallization layer
T1, T2 Access transistors
E Memory Element

1. A semiconductor memory device comprising:
at least one memory element in a semiconductor substrate including a phase transformation memory effect material, wherein the thermal coupling of the at least one memory element to areas surrounding the at least one memory element is reduced so as to reduce the thermal conductivity between that at least one memory element and the areas surrounding the at least one memory element; and
a cavity arrangement comprising at least one cavity in spatial proximity to the at least one memory element.

2. The semiconductor memory device of claim 1, further comprising:
a bottom access electrode device, a top access electrode device and a memory medium with a phase-dependent nonreactive resistance provided for each memory element, the memory medium being formed at least partly between and being contact-connected with the top and bottom access electrode devices;
wherein:
at least one of the access electrode devices includes an excitation electrode to locally heat the contact-connected memory medium to facilitate initiation of a corresponding phase transformation of the memory medium; and
at least one cavity is provided in spatial proximity to the excitation electrode of the respective access electrode device and/or the memory medium of each memory element, the at least one cavity providing thermal insulation between each memory element and the areas surrounding each memory element.

3. The semiconductor memory device of claim 2, wherein each excitation electrode is assigned a cavity of the cavity arrangement, and the assigned cavity directly adjoins at least a part of the excitation electrode.

4. The semiconductor memory device of claim 3, wherein the assigned cavity surrounds at least a part of the excitation electrode.

5. The semiconductor memory device of claim 2,wherein the excitation electrode is formed as a connecting region in relation to a source/drain region of a selection transistor disposed within the device.

6. The semiconductor memory device of claim 2, wherein the excitation electrode is formed in a trench structure in a substrate of the device.

7. The semiconductor memory device of claim 6, wherein the memory medium is formed as a material region of the excitation electrode and in an upper region of the trench structure.

8. The semiconductor memory device of claim 1, wherein the device includes a plurality of memory elements, and a common memory region or individual memory regions are provided for the plurality of memory elements.

9. The semiconductor memory device of claim 8, wherein the cavity arrangement is at least partly formed laterally between the plurality of memory elements.

10. The semiconductor memory device of claim 8, wherein the plurality of memory elements include a common second access electrode device or individual second access electrodes.

11. A method for producing a semiconductor memory device including at least one memory element with a phase transformation memory effect material, comprising:
thermally coupling the at least one memory element to areas surrounding the at least one memory element so as to reduce the thermal conductivity between the at least one memory element and the areas surrounding the at least one memory element;
wherein a cavity arrangement including at least one cavity is provided in spatial proximity to the at least one memory element.

12. The method of claim 11, further comprising:
providing for each memory element a bottom access electrode device, a top access electrode device, and a memory medium with a phase-dependent nonreactive resistance formed at least partly between the top and bottom access electrode devices, the memory medium being contact-connected to the top and bottom access electrode devices;
providing at least one of the access electrode devices with an excitation electrode configured to locally heat the contact-connected memory medium so as to initiate a corresponding phase transformation; and
providing at least one cavity in spatial proximity to the excitation electrode of the respective access electrode device and/or the memory medium of each memory element, the at least one cavity providing thermal insulation between each memory element and the areas surrounding each memory element.

13. The method of claim 11, wherein the excitation electrode is assigned a cavity of the cavity arrangement, and the assigned cavity directly adjoins at least a part of the excitation electrode.

14. The method of claim 13, wherein the assigned cavity is formed so as to surround at least a part of the excitation electrode.

15. The method of claim 12, wherein the excitation electrode is formed as a connecting region or plug region with respect to a source/drain region of a selection transistor disposed within the device.

16. The method of claim 12, wherein the excitation electrode is formed in a trench structure in a substrate of the device.

17. The method of claim 16, wherein the memory medium is formed as a material region of the excitation electrode in an upper region of the trench structure.

18. The method of claim 11, wherein a plurality of memory elements are provided, and a common memory region or individual memory regions are provided for the plurality of memory elements.

19. The method of claim 18, wherein the cavity arrangement is at least partly formed laterally between the plurality of memory elements.

20. The method of claim 18, further comprising:
providing a common second access electrode device or individual second access electrode devices to the plurality of memory elements.

21. The method of claim 11, further comprising:
lining the at least one cavity of the cavity arrangement with a thin layer of SiO₂ or BPSG.
